(19) United States
(12) Patent Application Publication
(10) Pub. No.: US 2009/0274826 A1
(43) Pub. Date: Nov. 5, 2009

(54) COATING APPARATUS CAPABLE OF CONTROLLING MIXING RATIO AND METHOD THEREOF

(75) Inventors: Jaehong WON, Gyeongsangnam-do (KR); Seonggwan CHEON, Ulsan (KR); Ingeun YUN, Daejeon (KR)

Correspondence Address: HARNESS, DICKEY & PIERCE, P.L.C., P.O. BOX 828, BLOOMFIELD HILLS, MI, 48303, US

(73) Assignee: SAMSUNG HEAVY IND. CO., LTD., Gyeongsangnam-do (KR)

(21) Appl. No.: 12/147,617

(22) Filed: Jun. 27, 2008

(30) Foreign Application Priority Data
May 2, 2008 (KR) 10-2008-0041286

(51) Int. Cl. C23C 16/52

(52) U.S. Cl. 427/8; 118/708

(57) ABSTRACT

A coating apparatus capable of controlling a mixing ratio includes a spindle motor unit having a spindle with which an upper end portion of a mixing ratio control shaft is engaged, the upper end portion of the control shaft being moved on the spindle in accordance with rotation of the spindle; and a control unit for calculating the mixing ratio of a main coating agent and a hardening agent based on measured flow rates thereof and controlling the rotation of the spindle when the calculated mixing ratio of the main coating agent and the hardening agent falls outside a tolerance range of a preset mixing ratio. The mixing ratio of the main coating agent and the hardening agent is adjusted depending on the positions of the upper end portion of the mixing ratio control shaft on the spindle.

### FIELD OF THE INVENTION

The present invention relates to a method and an apparatus capable of controlling a mixing ratio of a main coating agent and a hardening agent by adjusting a pump pressure, a temperature of a heater unit and a rotation of a spindle motor unit in accordance with a pressure, a temperature and a mixing ratio input by an operator when starting a coating operation.

### BACKGROUND OF THE INVENTION

As well known, in a ship manufacturing process, a coating operation is an important process required to prolong a lifespan of a ship and prevent corrosion of steel materials used for a framework of the ship. Conventionally, heavy duty protective coating compositions have been used for various parts of the ship, such as a hull, an exposed deck, an upper structure unit, a holding unit and a ballast tank.

For example, the hull includes a bottom to be always immersed in water, a topside positioned above water and a boot top to be immersed in water and exposed to the atmosphere repetitively, the boot top being provided between the bottom and the topside. When the hull is coated, a paint for the topside needs to be weather proof because the hull is exposed to intensive sunlight and rough waves. A paint for the bottom needs to be anti-fouling because the bottom is always immersed in water. A paint for the boot top needs to be weather proof, water proof and anti-fouling because the boot top is immersed in water and exposed to the atmosphere repetitively.

Therefore, in order to coat such parts with respective paints satisfying the above requirements, a plurality of dedicated primers are used to ensure bonding strength and anti-corrosiveness.

The conventional coating operation can be performed by a valve control method, a pneumatic control method and a control method using a gear pump. In the valve control method, flow rates of a main coating agent and a hardening agent supplied from a discharge terminal are measured by a flow rate sensor attached to a pneumatic part or a hydraulic part and controlled by the valve. However, this method is disadvantageous in that it is affected by accuracy of the valve, a temperature, a viscosity and a flow rate and also in that a flow rate of a paint is not controllable by the valve. Accordingly, it is difficult to perform a high quality coating operation.

In the pneumatic control method, flow rates of a main coating agent and a hardening agent are measured and controlled by the pneumatic control of the supply unit. In this method, a pressure and a flow rate can be controlled at a low pressure, but not at a high pressure. For example, a paint is discharged at a pressure of about 100 to 400 bar in a plunger type piston coating device.

Moreover, the control method using a gear pump has a constant flow rate property, and a flow rate of a paint can be controlled by controlling rotation of a gear. However, if the gear pump is connected to a coating device, two pumps need to be cleaned when exchanging paints. Thus, it is difficult to quickly change colors, which leads to deterioration of productivity. When the coating device is exclusively used, it is difficult to ensure a constant flow rate and an accurate mixing ratio. Meanwhile, when the gear pump is exclusively used, a high pressure (Max 100 bar) is hardly generated. Besides, a severe abrasion is caused by a pigment component of the paint, so that the equipment cost including the maintenance cost increases. Accordingly, this method cannot be applied to an actual coating apparatus for use in a ship.

### SUMMARY OF THE INVENTION

In view of the above, the present invention provides a coating apparatus such as, a seesaw type dual components coating apparatus which controls piston strokes of a main agent pump and a hardening agent pump, and its coating method which are capable of performing a coating operation while controlling a mixing ratio of a main coating agent and a hardening agent by adjusting a pump pressure, a temperature of a heater unit and a rotation of a spindle motor unit in accordance with a pressure, a temperature and a mixing ratio input by an operator in starting a coating operation.

In the present invention, a coating operation is performed while controlling a mixing ratio of a main coating agent and a hardening agent on the basis of 5% by controlling a pump pressure, a temperature of a heater unit and a rotation of a spindle motor unit so as to cope with a pressure, a temperature and a mixing ratio input by an operator in starting a coating operation in a seesaw type dual components coating apparatus. Accordingly, it is possible to solve the conventional problems in which a high quality coating cannot be performed because a flow rate of a paint is not controllable by a valve; a pressure and a flow rate cannot be controlled at a high pressure environment; a cleaning in changing paints and a quick color change cannot be performed when using a gear pump and a coating device connected with each other; and the accuracy of the mixing ratio cannot be improved when using a coating device exclusively.

Further, in the present invention, a seesaw type dual components coating apparatus is provided with a spindle motor unit, and a screw part of the spindle motor unit is engaged with an upper portion of a mixing ratio control shaft of a seesaw unit for controlling strokes of a main agent pump and a hardening agent pump. At this time, a number of rotation of the spindle is recorded at regular intervals from a start point to an end point of the screw part engaged with the upper portion of the mixing ratio control shaft, and a mixing ratio of a main coating agent and a hardening agent is controlled by controlling the number of rotation of the spindle. As a result, an optimal coating quality can be obtained.

In accordance with one aspect of the invention, there is provided A coating apparatus capable of controlling a mixing ratio including a spindle motor unit having a spindle with which an upper end portion of a mixing ratio control shaft is engaged, the upper end portion of the control shaft being moved on the spindle in accordance with rotation of the spindle; and a control unit for calculating the mixing ratio of a main coating agent and a hardening agent based on measured flow rates thereof and controlling the rotation of the spindle when the calculated mixing ratio of the main coating agent and the hardening agent falls outside a tolerance range of a preset mixing ratio; wherein the mixing ratio of the main coating agent and the hardening agent is adjusted depending on the positions of the upper end portion of the mixing ratio control shaft on the spindle.

In accordance with another aspect of the invention, there is provided a coating method using the coating apparatus including a spindle motor unit having a spindle for controlling a mixing ratio of a main coating agent and a hardening agent, the coating method including: setting a mixing ratio of the main coating agent and the hardening agent; rotating the spindle to meet the preset mixing ratio; measuring flow rates of the main coating agent and the hardening agent to calculate a mixing ratio thereof; rotating the spindle when the calculated mixing ratio falls outside a tolerance range with respect to the preset mixing ratio to adjust the calculated mixing ratio; and pumping the main coating agent and the hardening agent with the adjusted mixing ratio.

### BRIEF DESCRIPTION OF THE DRAWINGS

The above and other objects and features of the present invention will become apparent from the following description of embodiments, given in conjunction with the accompanying drawings, in which:

FIG. 1 shows a perspective view of a mixing ratio control apparatus for coating;

FIG. 2 describes a block diagram of a mixing ratio control apparatus in accordance with an embodiment of the present invention;

FIG. 3 provides a perspective view of a spindle motor unit of FIG. 2;

FIG. 4 is a cross sectional view showing that a motor is attached to a seesaw type coating device;

FIGS. 5A and 5B illustrate movement of a coating apparatus on the basis of rotation positions of the spindle motor unit of FIG. 2; and

FIGS. 6A and 6B present a flow chart sequentially depicting a mixing ratio controlled coating process in accordance with an embodiment of the present invention.

### DETAILED DESCRIPTION OF THE EMBODIMENT

Embodiments of the present invention will be described with reference to the accompanying drawings which form a part hereof.

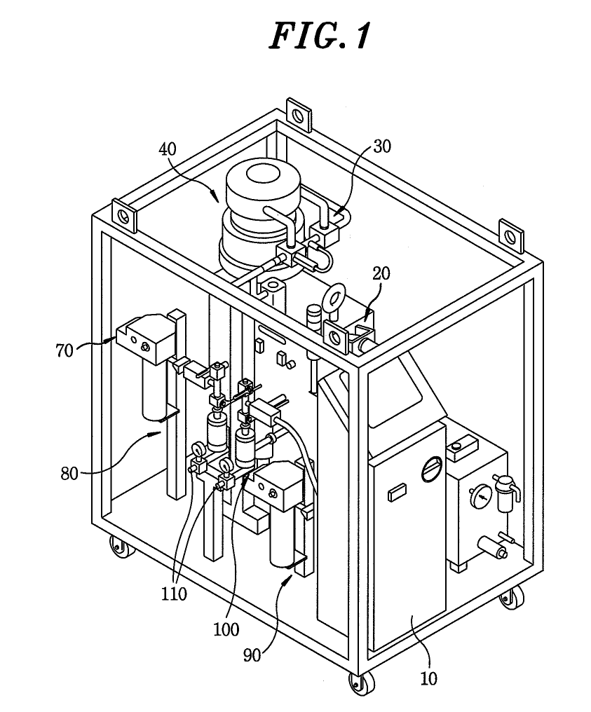

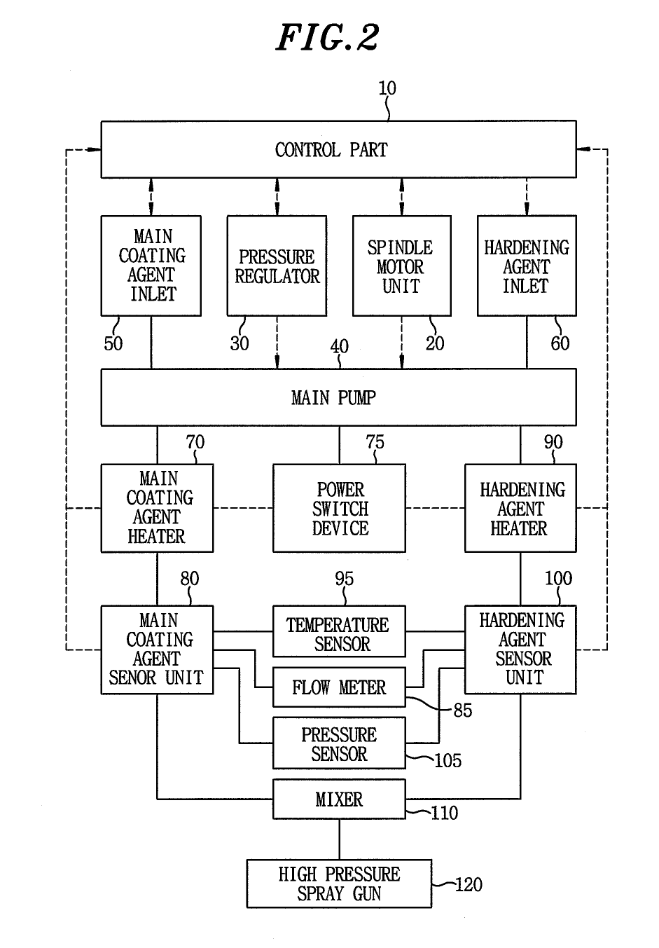

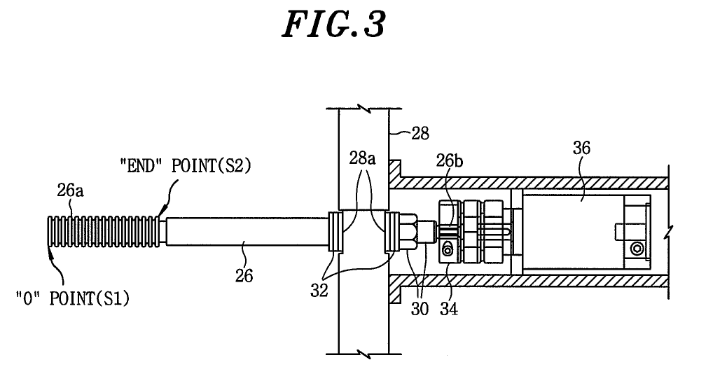

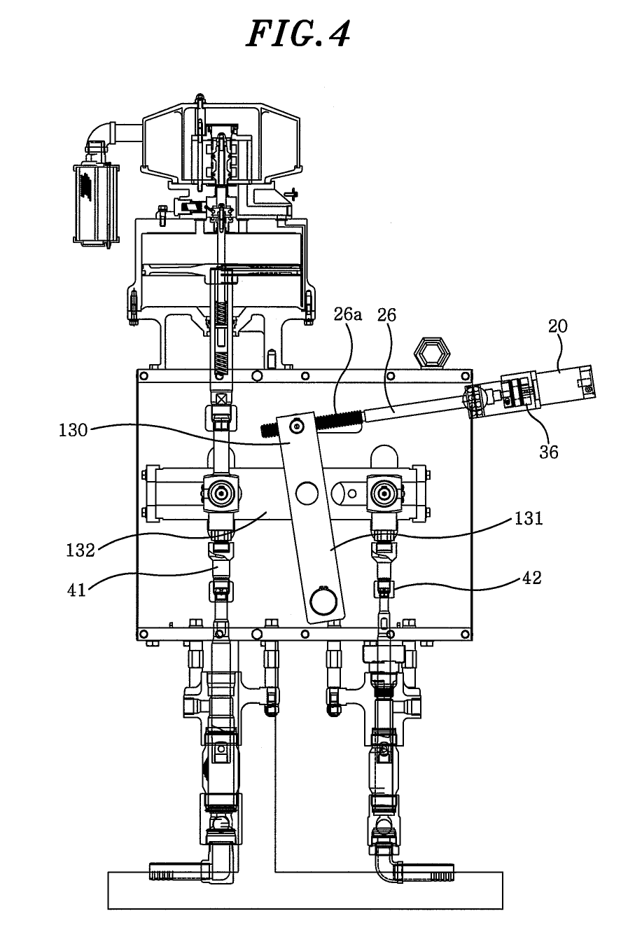

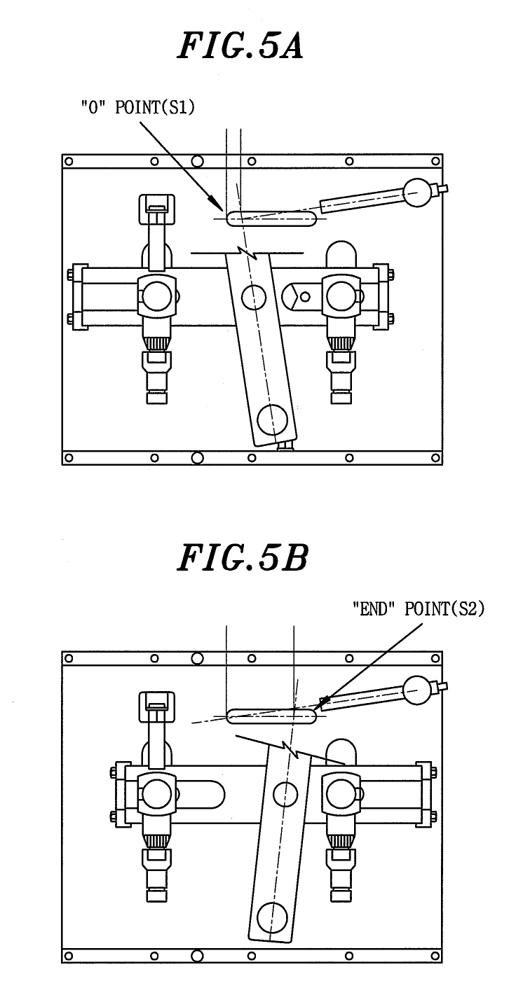

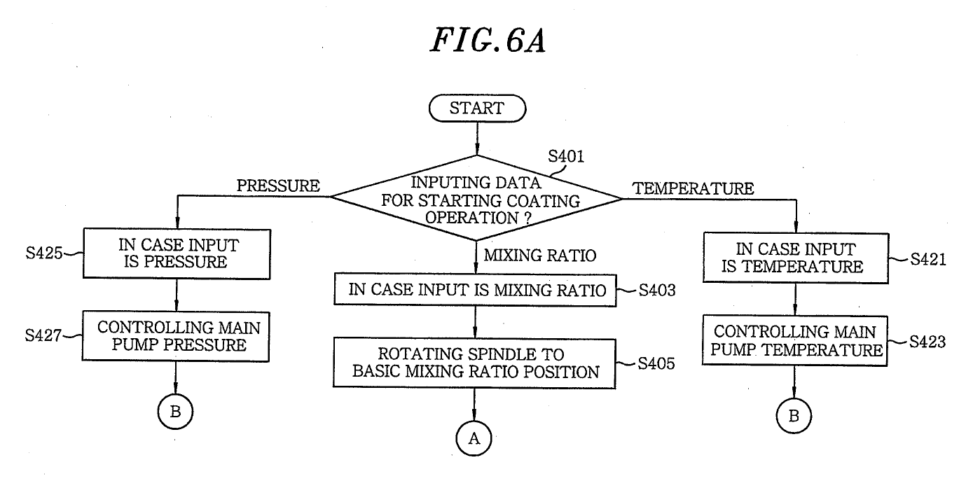

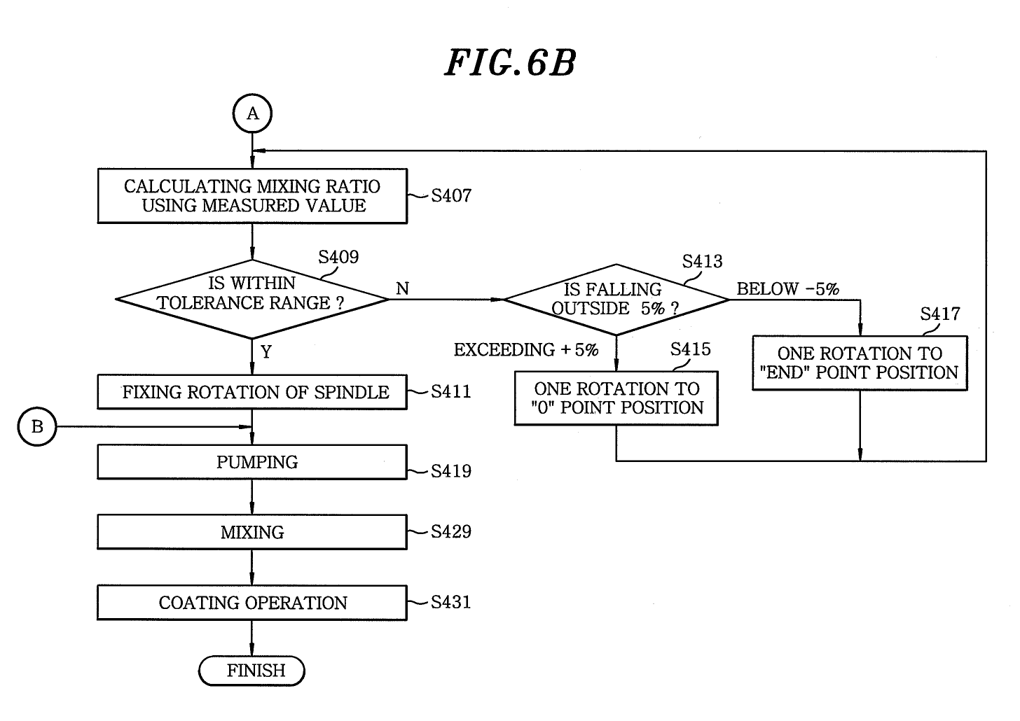

Referring to FIGS. 2 to 6, FIG. 2 is a block diagram of a coating apparatus capable of controlling a mixing ratio of a main coating agent and a hardening agent in accordance with an embodiment of the present invention. This coating apparatus includes a control unit 10, a spindle motor unit 20, a pressure regulator 30, a main pump 40, a main coating agent inlet 50, a hardening agent inlet 60, a main coating agent heater unit 70, a main coating agent sensor unit 80, a hardening agent heater unit 90, a hardening agent sensor unit 100, a mixer 110, a high pressure spray gun 120 and a seesaw unit 130. Here, FIG. 1 shows a three-dimensional view schematically showing the coating apparatus developed from a conceptual block diagram of FIG. 2. FIG. 3 provides a perspective view of the spindle motor unit 20 of FIG. 2. In FIG. 3, a motor 36 is engaged with a spindle 26 having at an end portion thereof a screw part 26a. FIG. 4 is a cross sectional view showing that a motor 36 is attached to a conventional seesaw type coating apparatus. In FIG. 4, a seesaw part 130 includes a mixing ratio control shaft 131 and a seesaw member 132, in which the screw part 26a is engaged with an upper portion of the mixing ration control shaft 131. In the conventional seesaw type coating apparatus, a stroke of respective main coating agent pump 41 and hardening agent pump 42 is controlled by a horizontal position of the seesaw member 132 moved by the mixing ratio control shaft 131, and detailed description thereof is omitted. FIGS. 5A and 5B illustrate movement of the coating apparatus on the basis of rotation positions of the spindle 26. FIGS. 6A and 6B present a flow chart sequentially depicting a mixing ratio controlled coating process.

In the control unit 10, numbers of rotations of the spindle 26 in accordance with mixing ratios, e.g., basic mixing ratios 2:1, 3:1, and 4:1, are stored in advance. Respective number of rotation is obtained by calculating the number of rotation of the spindle 26 needed to reach respective position of an upper end portion of the mixing ratio control shaft 131 corresponding to respective basic mixing ratio. When a mixing ratio, a temperature and a pressure are input by an operator for starting a coating operation, the control unit 10 controls the spindle motor unit 20 so that the upper end portion of the mixing ratio control shaft 131 moves in accordance with the input mixing ratio. Next, the control unit 10 calculates flow rates of the main coating agent and the hardening agent by using a flow meter 85 installed at the main coating agent sensor unit 80 and the hardening agent sensor unit 100. Air in a fitting and a hose connected to the coating apparatus needs to be removed. Therefore, data obtained during an initial predetermined time period (e.g., 2 minutes) after starting the coating apparatus is neglected, and flow rates measured after the initial predetermined time period are used as data. A mixing ratio of the main coating agent and the hardening agent is calculated based on the above data. When the calculated mixing ratio is within a tolerance range of the input mixing ratio (e.g., within ±5%), the position of the upper end portion of the mixing ratio control shaft 131 which is engaged with the screw part 26a of the spindle motor unit 20 is controlled to be fixed. However, when it falls outside the tolerance range, i.e., when it exceeds ±5%, the spindle motor unit 20 is controlled to rotate at 360° so that the upper end portion of the mixing ratio control shaft 131 moves toward “0” point S1 of the screw part 26a shown in FIG. 3. Meanwhile, when it is below −5%, the spindle motor unit 20 is controlled to rotate at 360° so that the upper end portion of the mixing ratio control shaft 131 moves toward “End” point S1 of the screw part 26a shown in FIG. 3.

Further, when a mixing ratio, a temperature and a pressure are input by an operator for starting a coating operation, the control unit 10 controls heating of the main coating agent heater unit 70 and the hardening agent heater unit 90 by feeding back thereto data measured by the temperature sensor 95 connected to the main coating agent sensor unit 80 and the hardening agent sensor unit 100 so that the temperature can be maintained near the input temperature. Here, the control unit 10 can control a temperature to be within a predetermined range by using a power switch device 75 having a bimetal device installed at the main coating agent heater unit 70 and the hardening agent heater unit 90.

Moreover, when a pressure measured by the pressure sensor 105 connected to the main coating agent sensor unit 80 and the hardening agent sensor unit 100 falls outside a maximum/minimum pressure range of the input pressure, the control unit 10 controls the pressure regulator 30 such that the pressure measured falls within the maximum/minimum pressure range.

The spindle motor unit 20 is an electric or a mechanical motor operated under the control of the control unit 10. As shown in the section view of the spindle motor unit 20 of FIG. 3, the spindle motor unit 20 includes bearings 32 formed at opposite sides of a fixed shaft 28, a coupling 34 for rotating a rotation part 26b of a spindle 26, and a motor 36 having a rotation break (not shown) for rotating and stopping the coupling 34. The screw part 26a is formed at one side of the spindle 26, and the rotation part 26b is formed at the other side of the spindle 26. The spindle 26 penetrates the fixed shaft 28. Grooves 28a are formed at opposite sides of the fixed shaft 28 so that the bearings 32 can be closely attached to the fixed shaft 28, and nut 31 is formed at one side of the bearing 32.

In case the spindle motor unit 20 is an electric motor, the motor 36 having the rotation break operated by an electromagnetic force is driven to rotate the coupling 34 under the control of the control unit 10. Next, the rotation part 26b rotates so that a mixing ratio of a main coating agent and a hardening agent in the main pump 40 can be controlled. Here, when the rotation part 26b of the spindle motor unit 20 rotates, the spindle 26 is rotated together therewith.

When the pressure falls outside the maximum/minimum pressure range, the pressure regulator 30 adjusts the pressure to fall within the maximum/minimum pressure range under the control of the control unit 10. Further, when the coating operation is completed, the pressure regulator 30 removes an internal pressure by blocking a pressure supplied to the main pump 40.

The main pump 40 includes the main coating agent pump 41 and the hardening agent pump 42, and pumps to the mixer 110 the main coating agent and the hardening agent which are respectively injected from the main coating agent inlet 50 and the hardening agent inlet 60 while controlling the mixing ratio thereof by the rotation of the spindle 26. Further, the main pump 40 pumps the main coating agent and the hardening agent to the mixer 110 at a pressure within the maximum/minimum pressure range by the pressure control of the pressure regulator 30.

The main coating agent inlet 50 injects a main coating agent to the main pump 40 under the control of the control unit 10, and the hardening agent inlet 60 injects the hardening agent to the main pump 40 under the control of the control unit 10.

The main coating agent heater unit 70 and the hardening agent heater unit 90 respectively heat the main coating agent and the hardening agent flowing into the mixer 110 to control the temperatures thereof under the control of the control unit 10. Here, the main coating agent heater unit 70 and the hardening agent heater unit 90 are provided with the power switch device 75 having a bimetal device, the temperature of the agents can be controlled so as not to exceed the preset temperature of the control unit 10.

The main coating agent sensor unit 80 and the hardening agent sensor unit 100 are provided with the flow meter 85, the temperature sensor 95 and the pressure sensor 105. The flow meter 85 measures a flow rate, and the flow rate is provided to the control unit 10, the data obtained by the temperature sensor 95 is provided to the control unit 10, and a measured pressure by the pressure sensor 105 is provided to the control unit 10. Here, the flow rate measured by the flow meter 85 varies depending on the accuracy of the flow meter 85, so that a calibration of the flow meter is preferred, which is done by examining whether a variation between a measured flow rate with respect to viscosity of used fluid, e.g., a volume converted from a measured weight per unit time with known specific gravity of the fluid, and a flow rate per minute measured by the flow meter is within an accuracy of 1%.

The mixer 110 mixes the main coating agent and the hardening agent which are pumped from the main pump 40 at a controlled mixing ratio and, then, the mixed agent is sprayed by the high pressure spray gun 120, thereby performing an actual coating operation. When the coating operation is completed, the mixer 110 having the mixture of the main coating agent and the hardening agent is cleaned by injecting a cleaning agent (e.g., thinner).

Therefore, in the present invention, a coating operation is performed while controlling a mixing ratio of a main coating agent and a hardening agent by controlling a pump pressure, a temperature of a heating unit and a rotation of a spindle motor unit in accordance with a pressure, a temperature and a mixing ratio input by an operator when starting a coating operation in a seesaw type dual components coating apparatus. As a consequence, it is possible to solve the following conventional problems that: a high quality coating cannot be performed because a flow rate of a paint is not controllable by a valve; a pressure and a flow rate cannot be controlled at a high pressure environment; a cleaning upon exchange of paints and a quick color change cannot be performed when using a gear pump and a coating apparatus connected with each other; and the accuracy of the mixing ratio cannot be improved when using a coating device exclusively.

Hereinafter, a mixing ratio controlled coating process performed by using the coating apparatus configured as described above will be described.

FIGS. 6A and 6B is a flow chart depicting sequentially a mixing ratio controlled coating process in accordance with an embodiment of the present invention.

First of all, when a coating operation is started, data input by an operator is checked (S401).

If it is checked in the step S401 that the input data is a mixing ratio (S403), the control unit 10 controls the spindle motor unit 20 to move the upper end portion of the mixing ratio control shaft 131 in accordance with the input mixing ratio by using above mentioned prestored mixing ratio related data.

Next, the control unit 10 measures flow rates of the main coating agent and the hardening agent by using the flow meters 85 installed at the main coating agent sensor unit 80 and the hardening agent sensor unit 100. It is required to first remove air in the fitting and the hose connected to the coating apparatus. Therefore, data obtained during an initial predetermined time period (e.g., 2 minutes) after operating the coating apparatus is neglected, and a flow rate measured after the initial predetermined time period is used as data. A mixing ratio of the main coating agent and the hardening agent is calculated based on the above data (S407).

Next, the control unit 10 checks whether or not the calculated mixing ratio falls within a predetermined range (e.g., ±5%) of the mixing ratio input by the operator (S409).

If it is checked in the step S409 that it falls within the predetermined range, the spindle motor unit 20 is controlled to stop. Then, in the spindle motor unit 20, the motor 36 having a rotation break stops under the control of the control unit 10, thereby stopping the rotation part 26b (S411).

If it is checked in the step S409 that it falls outside the predetermined range (S413), for example, if it is beyond +5%, the spindle motor unit 20 is controlled to rotate at 360° so that the upper end portion of mixing ratio control shaft 131 moves toward “0” point S1 of the screw part 26a shown in FIG. 3 (S415). Meanwhile, when it is below −5%, the spindle motor unit 20 is controlled to rotate at 360° so that the upper portion of the mixing ratio control shaft 131 moves toward “End” point S2 of the screw part 26a in FIG. 3 (S417).

In this way, in the spindle motor unit 20, in case it is an electric type, the motor 36 having a rotation break operated by an electromagnetic force is driven to rotate the coupling 34 and the rotation part 26b under the control of the control unit 10. As a consequence, when the rotation part 26b rotates, the spindle 26 is rotated together therewith, thereby controlling the position of the upper end portion of the mixing ratio control shaft 131 engaged with the screw part 26a. The strokes of the main agent pump 41 and the hardening agent pump 42 installed at the main pump 40 are controlled in accordance with the positions of the upper end portion of the mixing ratio control shaft 131 on the screw part 26a, thereby controlling a mixing ratio of the main coating agent and the hardening agent.

Here, the control unit 10 calculates an actual mixing ratio by measuring in real time flow rates of the main coating agent and the hardening agent and rechecks whether or not the calculated mixing ratio is within a predetermined range (±5%) of the input mixing ratio, and controls the rotation of the spindle motor unit 20 until the calculated mixing ratio falls within the predetermined range.

Thereafter, the main pump 40 pumps (S419) to the mixer 110 the main coating agent and the hardening agent which are injected from the main coating agent inlet 50 and the hardening agent inlet 60 while controlling a mixing ratio thereof by the rotation of the spindle motor unit 20.

Meanwhile, if it is checked in the step S401 that the input data is a temperature (S421), the heating of the main coating agent heater unit 70 and the hardening agent heater unit 90 is controlled by feeding back thereto data measured by the temperature sensors 95 connected to the main coating agent sensor unit 80 and the hardening agent sensor unit 100 so that the temperature can be maintained at near the input temperature.

The main coating agent heater unit 70 and the hardening agent heater unit 90 heats the agents flowing into the mixer 110 to control the temperature thereof under the control of the control unit 10 (S423). Here, the main coating agent heater unit 70 and the hardening agent heater unit 90 are provided with the power switch device 75 having a bimetal device, so that the temperature can be controlled so as not to exceed the preset temperature of the control unit 10.

Furthermore, if it is determined in S401 that the input data is a pressure (S425), the pressure regulator 30 is controlled so that a pressure measured by the pressure sensor 105 connected to the main coating agent sensor unit 80 and the hardening agent sensor unit 100 is within the maximum/minimum range of the input pressure. When the pressure falls outside the maximum/minimum pressure range, the pressure regulator 30 is controlled such that the measured pressure becomes within the maximum/minimum pressure range under the control of the control unit 10 (S427).

The main pump 40 pumps to the mixer 110 the main coating agent and the hardening agent at a pressure within the maximum/minimum pressure range under the control of the pressure regulator 30.

The mixer 110 mixes (S429) the main coating agent and the hardening agent pumped from the main pump 40 at a controlled mixing ratio, and the mixed agent is sprayed by the high pressure spray gun 120, thereby performing an actual coating operation (S431). At this time, when the coating operation is completed, the mixer 110 having the mixture of the main coating agent and the hardening agent is cleaned by injecting a cleaning agent (e.g., thinner). Further, the pressure regulator 30 removes an internal pressure by blocking a pressure supplied to the main pump 40.

In the present invention, the seesaw type dual components coating apparatus is provided with the spindle motor unit, and the screw part of the spindle motor unit is engaged with the upper portion of the mixing ratio control shaft of a seesaw unit for controlling strokes of a main agent pump and a hardening agent pump. At this time, the numbers of rotations of the spindle, which correspond to positions of the upper end portion of the mixing ratio control shaft on the screw part from a start point to the end point thereof are saved, and a mixing ratio of the main coating agent and the hardening agent is controlled by controlling the number of rotation of the spindle. As a result, an optimal coating quality can be obtained.

While the invention has been shown and described with respect to the embodiments, it will be understood by those skilled in the art that various changes and modification may be made without departing from the scope of the invention as defined in the following claims.

What is claimed is:

1. A coating apparatus capable of controlling a mixing ratio comprising:
a spindle motor unit having a spindle with which an upper end portion of a mixing ratio control shaft is engaged, the upper end portion of the control shaft being moved on the spindle in accordance with rotation of the spindle; and
a control unit for calculating the mixing ratio of a main coating agent and a hardening agent based on measured flow rates thereof and controlling the rotation of the spindle when the calculated mixing ratio of the main coating agent and the hardening agent falls outside a tolerance range of a preset mixing ratio;
wherein the mixing ratio of the main coating agent and the hardening agent is adjusted depending on the positions of the upper end portion of the mixing ratio control shaft on the spindle.

2. The coating apparatus of claim 1, further comprising:
a main pump for pumping the main coating agent and the hardening agent with the preset mixing ratio, respectively;
a mixing unit for mixing the main coating agent and the hardening agent pumped by the main pump;
a pressure regulator for controlling a pressure of the main coating agent and the hardening coating agent supplied to the main pump;
a main coating agent heater unit and a hardening agent heater unit for heating the agents flowing into the mixing unit, respectively;
a main coating agent sensor unit and a hardening agent sensor unit for measuring flow rates, temperatures, and pressures; and
a high pressure spray gun for spraying a mixed paint in the mixing unit at a high pressure.

3. The coating apparatus of claim 2, wherein the control unit controls heating of the main coating agent heater unit and the hardening agent heater unit using the sensor units so that a temperature preset for a coating operation is maintained.

4. The coating apparatus of claim 2, wherein the main coating agent heater unit and the hardening agent heater unit include bimetal devices, respectively.

5. The coating apparatus of claim 2, wherein the control unit controls the pressure regulator using the sensor units so that a pressure preset for a coating operation is maintained.

6. The coating apparatus of claim 1, wherein the spindle motor unit further includes:
a fixed shaft supporting the spindle;
bearings installed at opposite sides of the fixed shaft;
a screw part formed at an end portion of the spindle where the mixing ratio control shaft is engaged therewith;
a rotation part formed at another end portion of the spindle;
a motor having a coupling fixed to the rotation part and a rotation break, the motor rotating or stopping the coupling; and
a nut disposed between the bearings and the coupling.

7. The coating apparatus of claim 6, wherein the tolerance range is ±5%.

8. The coating apparatus of claim 7, wherein when the calculated mixing ratio exceeds +5% of the tolerance range, the spindle rotates so that the upper portion of the mixing ratio control shaft moves toward a free end of the screw part.

9. The coating apparatus of claim 7, wherein when the calculated mixing ratio is below −5% of the tolerance range, the spindle rotates so that the upper portion of the mixing ratio control shaft moves in an opposite direction of the free end of the screw part.

10. A coating method using the coating apparatus including a spindle motor unit having a spindle for controlling a mixing ratio of a main coating agent and a hardening agent, the coating method comprising:
setting a mixing ratio of the main coating agent and the hardening agent;
rotating the spindle to meet the preset mixing ratio;
measuring flow rates of the main coating agent and the hardening agent to calculate a mixing ratio thereof;
rotating the spindle when the calculated mixing ratio falls outside a tolerance range with respect to the preset mixing ratio to adjust the calculated mixing ratio; and
pumping the main coating agent and the hardening agent with the adjusted mixing ratio.

11. The coating method of claim 10, wherein the tolerance range is ±5%.

12. The coating method of claim 10, further comprising:
setting a temperature of the main coating agent and the hardening agent; and
controlling a temperature of the main coating agent and the hardening agent to be within the preset temperature while measuring the temperature thereof.

13. The coating method of claim 10, further comprising:
setting a pressure of the main coating agent and the hardening agent; and
controlling a pressure of the main coating agent and the hardening agent to be within the preset pressure while measuring the pressure thereof.
